(19) United States
(12) Patent Application Publication
(10) Pub. No.: US 2021/0159883 A1
(43) Pub. Date: May 27, 2021

(54) ENERGY CONFINEMENT IN ACOUSTIC WAVE DEVICES

(71) Applicants: TOHOKU UNIVERSITY, Sendai-shi (JP); SKYWORKS SOLUTIONS, INC., Irvine, CA (US)

(72) Inventors: Michio KADOTA, Sendai-Shi (JP); Shuji TANAKA, Sendai-Shi (JP); Yoshimi ISHII, Sendai-Shi (JP); Hiroyuki NAKAMURA, Kadoma-Shi (JP); Keiichi MAKI, Kadoma-Shi (JP); Rei GOTO, Kadoma-Shi (JP)

(21) Appl. No.: 17/100,928

(22) Filed: Nov. 22, 2020

Related U.S. Application Data
(60) Provisional application No. 62/941,683, filed on Nov. 27, 2019.

(51) Int. Cl. H03H 9/10; H03H 3/08; H03H 9/02; H03H 9/145; H03H 9/25; H03H 9/64

(52) U.S. Cl. CPC H03H 9/1092; H03H 3/08; H03H 9/02637; H03H 9/64; H03H 9/145; H03H 9/25; H03H 9/02559

(57) ABSTRACT

Energy confinement in acoustic wave devices. In some embodiments, a surface acoustic wave device can include a quartz substrate, a piezoelectric film formed from LiTaO₃ or LiNbO₃ and disposed over the quartz substrate, and an interdigital transducer electrode formed over the piezoelectric film. The surface acoustic wave device can further include a bonding layer implemented over the piezoelectric film, and a cap layer formed over the bonding layer to thereby substantially confine energy of a propagating wave below the cap layer.

### CROSS-REFERENCE TO RELATED APPLICATION(S)

This application claims priority to U.S. Provisional Application No. 62/941,683 filed Nov. 27, 2019, entitled ENERGY CONFINEMENT IN ACOUSTIC WAVE DEVICES, the disclosure of which is hereby expressly incorporated by reference herein in its entirety.

### BACKGROUND

### Field

The present disclosure relates to acoustic wave devices such as surface acoustic wave (SAW) devices.

### Description of the Related Art

A surface acoustic wave (SAW) resonator typically includes an interdigital transducer (IDT) electrode implemented on a surface of a piezoelectric layer. Such an electrode includes two interdigitized sets of fingers, and in such a configuration, the distance between two neighboring fingers of the same set is approximately the same as the wavelength λ of a surface acoustic wave supported by the IDT electrode.

In many applications, the foregoing SAW resonator can be utilized as a radio-frequency (RF) filter based on the wavelength λ. Such a filter can provide a number of desirable features.

### SUMMARY

In accordance with a number of implementations, the present disclosure relates to a surface acoustic wave device that includes a quartz substrate and a piezoelectric film formed from LiTaO₃ or LiNbO₃ and disposed over the quartz substrate. The surface acoustic wave device further includes an interdigital transducer electrode formed over the piezoelectric film, and a bonding layer implemented over the piezoelectric film. The surface acoustic wave device further includes a cap layer formed over the bonding layer to thereby substantially confine energy of a propagating wave below the cap layer.

In some embodiments, the bonding layer can be formed from SiO₂. In some embodiments, the cap layer can be formed from Si.

In some embodiments, the interdigital transducer electrode can be formed directly on an upper surface of the piezoelectric film, and a lower surface of the cap layer can be in direct contact with an upper surface of the bonding layer. In some embodiments, the bonding layer can encapsulate the interdigital transducer electrode. In some embodiments, a volume above the interdigital transducer electrode can include a cavity defined by the upper surface of the piezoelectric film and the lower surface of the cap layer, such that the interdigital transducer electrode is exposed to the cavity.

In some embodiments, the cavity can be further defined laterally by a side wall. In some embodiments, the side wall can be formed by a peripheral portion of the bonding layer. In some embodiments, the side wall can be formed by a wall structure at least partially embedded within the bonding layer.

In some embodiments, the wall structure can include one or more trenches filled with SiN, with the one or more trenches partially or fully surrounding the cavity. In some embodiments, the one or more trenches can include a single trench that substantially surrounds the cavity.

In some embodiments, the cap layer can define one or more openings resulting from formation of the cavity.

In some embodiments, the acoustic wave device can further include first and second contact pads formed over the piezoelectric film and electrically connected to the interdigital transducer electrode. In some embodiments, the acoustic wave device can further include a conductive via that extends from each of the first and second contact pads to an upper surface of the cap layer.

In some embodiments, the acoustic wave device can further include first and second reflectors implemented on the piezoelectric film and positioned on first and second sides of the interdigital transducer electrode.

According to some implementations, the present disclosure relates to a method for fabricating an acoustic wave device. The method includes forming or providing a piezoelectric layer formed from LiTaO₃ or LiNbO₃, and forming an interdigital transducer electrode over the piezoelectric layer. The method further includes implementing a bonding layer over the piezoelectric layer, and bonding a cap layer onto the bonding layer such that the bonding layer is between the cap layer and the piezoelectric layer. The cap layer is configured to allow confinement of energy of a propagating wave to a volume below the cap layer. The method further includes thinning the piezoelectric layer to provide a piezoelectric film.

In some embodiments, the method can further include attaching a quartz substrate onto the piezoelectric film. The piezoelectric layer can have first and second surfaces, such that the interdigital transducer electrode is formed on the first surface of the piezoelectric layer, and the boding layer is implemented on the first surface of the piezoelectric layer.

In some embodiments, the thinning of the piezoelectric layer can be performed on the side of the second surface of the piezoelectric layer to result in a new second surface on the piezoelectric film. The attaching of the quartz substrate onto the piezoelectric film can include bonding of the quartz substrate onto the new second surface of the piezoelectric film.

In some embodiments, the implementing of the bonding layer can result in the bonding layer encapsulating the interdigital transducer electrode. In some embodiments, the implementing the bonding layer can result in a cavity above the interdigital transducer electrode and defined by the first surface of the piezoelectric film and a lower surface of the cap layer, such that the interdigital transducer electrode is exposed to the cavity.

In some embodiments, the cavity can be further defined laterally by a side wall. In some embodiments, the implementing of the bonding layer can further result in the side wall being formed by a peripheral portion of the bonding layer.

In some embodiments, the method can further include embedding a wall structure at least partially within the bonding layer, such that the wall structure forms the side wall of the cavity.

In some embodiments, the method can further include forming first and second conductive vias through the cap layer and the bonding layer to provide an electrical connection for each of first and second contact pads associated with the interdigital transducer electrode to a location at or near an upper surface of the cap layer.

According to some implementations, the present disclosure relates to a radio-frequency filter that includes an input node for receiving a signal and an output node for providing a filtered signal. The radio-frequency filter further includes an acoustic wave device implemented to be electrically between the input node and the output node to generate the filtered signal. The acoustic wave device includes a quartz substrate, a piezoelectric film formed from LiTaO₃ or LiNbO₃ and disposed over the quartz substrate, and an interdigital transducer electrode formed over the piezoelectric film. The surface acoustic wave device further includes a bonding layer implemented over the piezoelectric film, and a cap layer formed over the bonding layer to thereby substantially confine energy of a propagating wave below the cap layer.

In some implementations, the present disclosure relates to a radio-frequency module that includes a packaging substrate configured to receive a plurality of components, and a radio-frequency circuit implemented on the packaging substrate and configured to support either or both of transmission and reception of signals. The radio-frequency module further includes a radio-frequency filter configured to provide filtering for at least some of the signals. The radio-frequency filter includes a surface acoustic wave device having a quartz substrate, a piezoelectric film formed from LiTaO₃ or LiNbO₃ and disposed over the quartz substrate, and an interdigital transducer electrode formed over the piezoelectric film. The surface acoustic wave device further includes a bonding layer implemented over the piezoelectric film, and a cap layer formed over the bonding layer to thereby substantially confine energy of a propagating wave below the cap layer.

In some implementations, the present disclosure relates to a wireless device that includes a transceiver, an antenna, and a wireless system implemented to be electrically between the transceiver and the antenna. The wireless system includes a filter configured to provide filtering functionality for the wireless system. The filter includes a surface acoustic wave device having a quartz substrate, a piezoelectric film formed from LiTaO₃ or LiNbO₃ and disposed over the quartz substrate, and an interdigital transducer electrode formed over the piezoelectric film. The surface acoustic wave device further includes a bonding layer implemented over the piezoelectric film, and a cap layer formed over the bonding layer to thereby substantially confine energy of a propagating wave below the cap layer.

For purposes of summarizing the disclosure, certain aspects, advantages and novel features of the inventions have been described herein. It is to be understood that not necessarily all such advantages may be achieved in accordance with any particular embodiment of the invention. Thus, the invention may be embodied or carried out in a manner that achieves or optimizes one advantage or group of advantages as taught herein without necessarily achieving other advantages as may be taught or suggested herein.

### BRIEF DESCRIPTION OF THE DRAWINGS

FIG. 1 shows an example of a surface acoustic wave (SAW) device implemented as a SAW resonator.

FIG. 2 shows an enlarged and isolated plan view of an example interdigital transducer (IDT) electrode implemented on the SAW resonator of FIG. 1.

FIG. 3 shows that in some embodiments, a SAW resonator can include a combination of a quartz substrate, a piezoelectric layer, an interdigital transducer (IDT) electrode, a bonding layer implemented over the piezoelectric layer, and a cap layer formed over the bonding layer.

FIG. 4 shows that in some embodiments, the SAW resonator of FIG. 3 can be configured to provide electrical connections for the IDT electrode, and to include an internal structure generally over the IDT electrode.

FIG. 5 shows a more specific example of the SAW resonator of FIG. 4.

FIG. 6 shows another more specific example of the SAW resonator of FIG. 4.

FIG. 7 shows yet another more specific example of the SAW resonator of FIG. 4.

FIGS. 8A to 8H show an example process that can be utilized to manufacture the example SAW resonator of FIG. 5.

FIGS. 9A to 9D show an example process that can be utilized to manufacture the example SAW resonator of FIG. 6.

FIGS. 10A to 10H show an example process that can be utilized to manufacture the example SAW resonator of FIG. 7.

FIG. 11 shows that in some embodiments, multiple units of SAW resonators can be fabricated while in an array form.

FIG. 12 shows that in some embodiments, a SAW resonator having or more features as described herein can be implemented as a part of a packaged device.

FIG. 13 shows that in some embodiments, the SAW resonator based packaged device of FIG. 12 can be a packaged filter device.

FIG. 14 shows that in some embodiments, a radio-frequency (RF) module can include an assembly of one or more RF filters.

FIG. 15 depicts an example wireless device having one or more advantageous features described herein.

### DETAILED DESCRIPTION OF SOME EMBODIMENTS

The headings provided herein, if any, are for convenience only and do not necessarily affect the scope or meaning of the claimed invention.

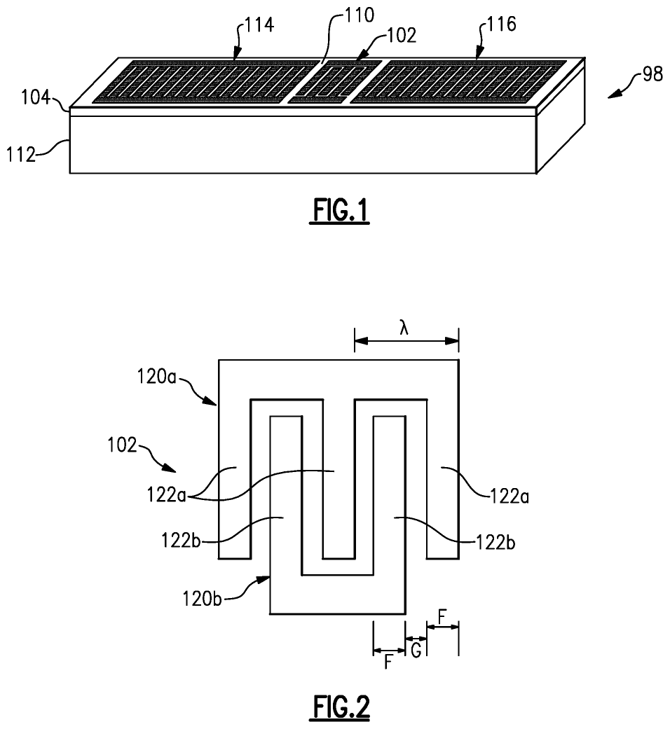

FIG. 1 shows an example of a surface acoustic wave (SAW) device 98 implemented as a SAW resonator. Such a SAW resonator can include a piezoelectric layer 104 formed of, for example, LiTaO₃ (also referred to herein as LT) or LiNbO₃ (also referred to herein as LN). Such a piezoelectric layer can include a first surface 110 (e.g., an upper surface when the SAW resonator 98 is oriented as shown) and an opposing second surface. The second surface of the piezoelectric layer 104 can be attached to, for example, a quartz substrate 112.

On the first surface 110 of the piezoelectric layer 104, an interdigital transducer (IDT) electrode 102 can be implemented, as well as one or more reflector assemblies (e.g., 114, 116). FIG. 2 shows an enlarged and isolated plan view of the IDT electrode 102 of the SAW resonator 98 of FIG. 1. It will be understood that the IDT electrode 102 of FIGS. 1 and 2 can included more or less numbers of fingers for the two interdigitized sets of fingers.

In the example of FIG. 2, the IDT electrode 102 is shown to include a first set 120a of fingers 122a and a second set 120b of fingers 122b arranged in an interdigitized manner. In such a configuration, the distance between two neighboring fingers of the same set (e.g., neighboring fingers 122a of the first set 120a) is approximately the same as the wavelength λ of a surface acoustic wave associated with the IDT electrode 102.

In the example of FIG. 2, various dimensions associated with the fingers are shown. More particularly, each finger (122a or 122b) is shown to have a lateral width of F, and a gap distance of G is shown to be provided between two interdigitized neighboring fingers (122a and 122b).

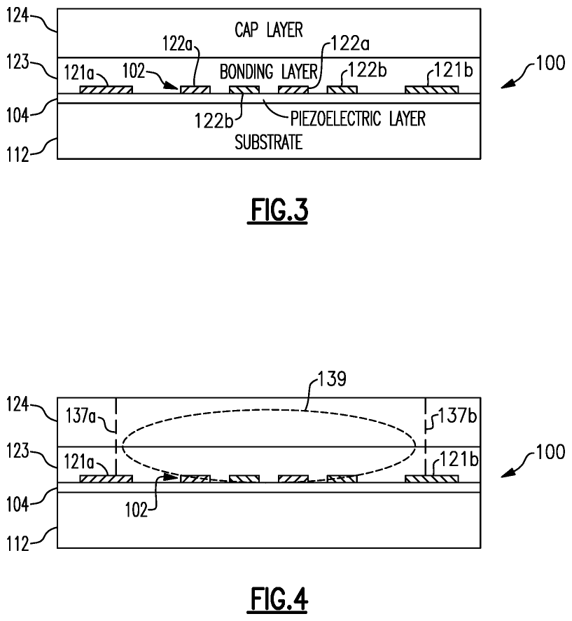

FIG. 3 shows that in some embodiments, a SAW resonator 100 can include a combination of a quartz substrate 112, a piezoelectric layer 104 (e.g., a film formed from LiTaO₃ or LiNbO₃), and an interdigital transducer (IDT) electrode 102 similar to the example of FIG. 1. Such an IDT electrode can be similar to the example of FIG. 2, and include first and second sets of fingers 122a, 122b arranged in an interdigitized manner. For the purpose of description, the first set of fingers 122a can be electrically connected to a first contact pad 121a, and the second set of fingers 122b can be electrically connected to a second contact pad 121b.

FIG. 3 shows that the SAW resonator 100 can further include a bonding layer 123 (e.g., silicon dioxide (SiO₂)) implemented over the piezoelectric layer 104. In some embodiments, such a bonding layer can be implemented to partially or fully encapsulate the IDT electrode 102 and the corresponding contact pads 121a, 121b.

FIG. 3 shows that in some embodiments, the SAW resonator 100 can further include a cap layer 124 (e.g., silicon (Si)) formed over the bonding layer 123. In some embodiments, such a cap layer can be configured to substantially confine energy of a propagating wave within the bonding layer 123 and/or the piezoelectric layer 104.

FIG. 4 shows that in some embodiments, the SAW resonator 100 of FIG. 3 can be configured to provide electrical connections 137a, 137b for the IDT electrode 102 (e.g., through the respective contact pads 121a, 121b). Examples related to such electrical connections are described herein in greater detail.

FIG. 4 also shows that in some embodiments, the SAW resonator 100 of FIG. 3 can be configured to include an internal structure 139 generally over the IDT electrode 102. Examples related to such an internal structure are described herein in greater detail.

FIG. 5 shows a more specific example of the SAW resonator 100 of FIG. 4. In the example of FIG. 5, electrical connections (137a, 137b in FIG. 4) can be implemented as first and second conductive vias 125a, 125b formed through the cap layer 124 and the bonding layer 123. Accordingly, the first via 125a can provide an electrical connection between the first contact pad 121a and an exposed surface 126a (of the first via 125a) at or near the upper surface 127 of the cap layer 124. Similarly, the second via 125b can provide an electrical connection between the second contact pad 121b and an exposed surface 126b (of the second via 125b) at or near the upper surface 127 of the cap layer 124.

In the example of FIG. 5, an internal structure (139 in FIG. 4) can be implemented such that the bonding layer 123 substantially encapsulates the IDT electrode 102 and the contact pads 121a, 121b. In such a configuration, the cap layer 124 can be a solid layer other than the conductive vias 125a, 125b extending therethrough.

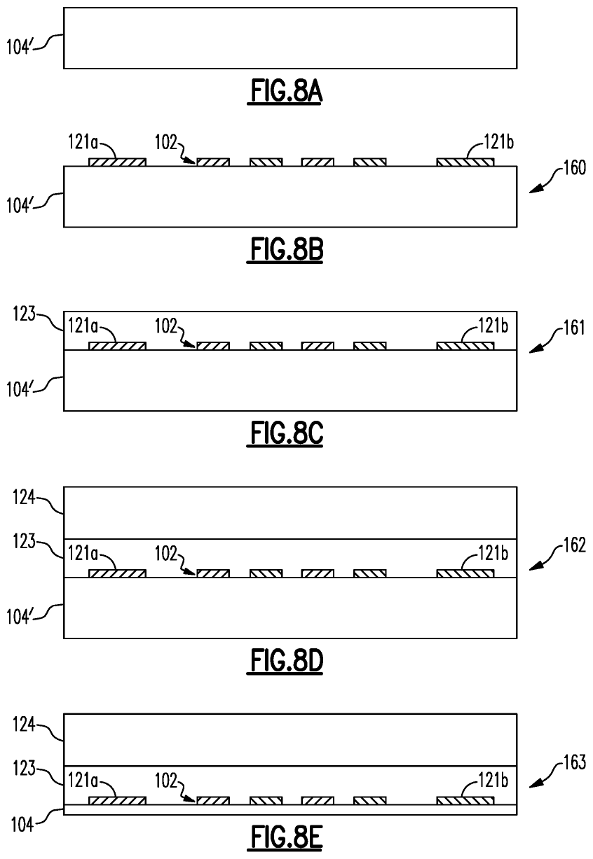

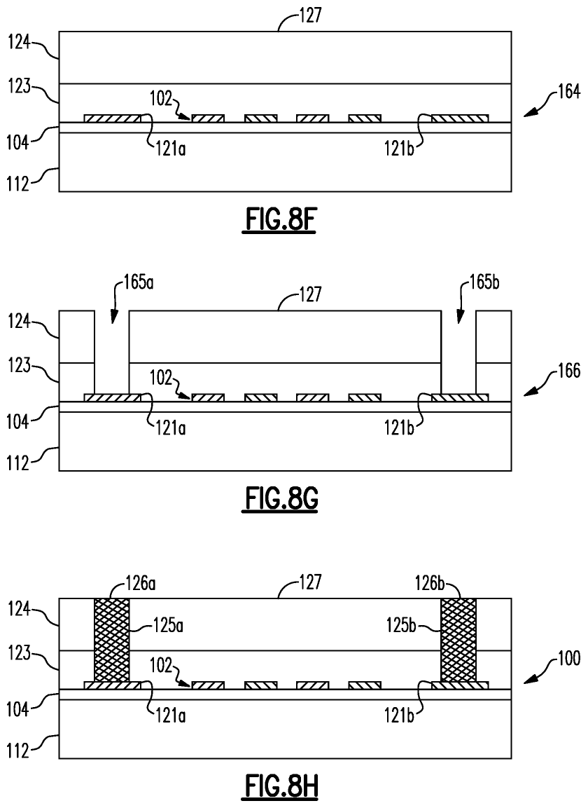

An example of a process that can be utilized to fabricate the SAW resonator 100 of FIG. 5 is described herein in reference to FIGS. 8A-8H.

FIG. 6 shows another more specific example of the SAW resonator 100 of FIG. 4. In the example of FIG. 6, electrical connections (137a, 137b in FIG. 4) can be implemented as first and second conductive vias 125a, 125b formed through the cap layer 124 and the bonding layer 123. Accordingly, the first via 125a can provide an electrical connection between the first contact pad 121a and an exposed surface 126a (of the first via 125a) at or near the upper surface 127 of the cap layer 124. Similarly, the second via 125b can provide an electrical connection between the second contact pad 121b and an exposed surface 126b (of the second via 125b) at or near the upper surface 127 of the cap layer 124.

In the example of FIG. 6, an internal structure (139 in FIG. 4) can be implemented such that a cavity 128 is provided over the IDT electrode 102. In some embodiments, such a cavity can be defined by an upper surface of the piezoelectric layer 104, an underside surface of the cap layer 124, and a peripheral portion of the bonding layer 123. In such a configuration, the cap layer 124 can include one or more openings 129 extending therethrough and dimensioned to allow formation of the cavity 128.

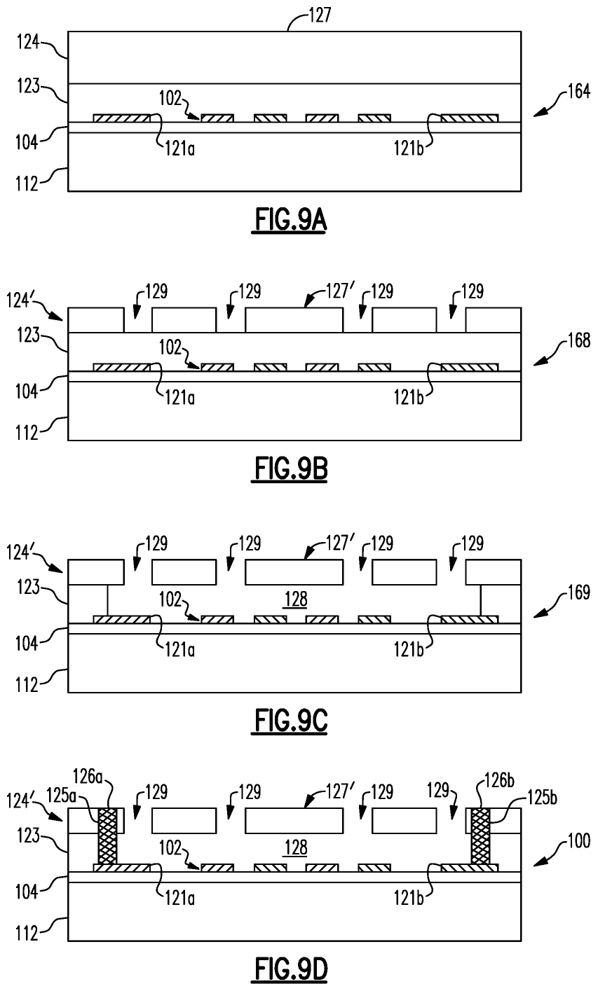

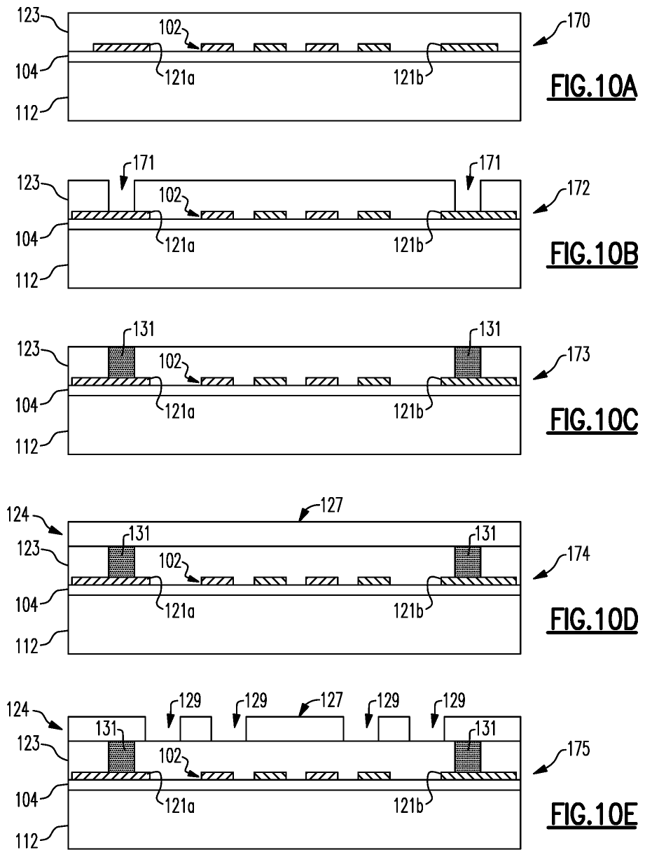

An example of a process that can be utilized to fabricate the SAW resonator 100 of FIG. 6 is described herein in reference to FIGS. 9A-9D.

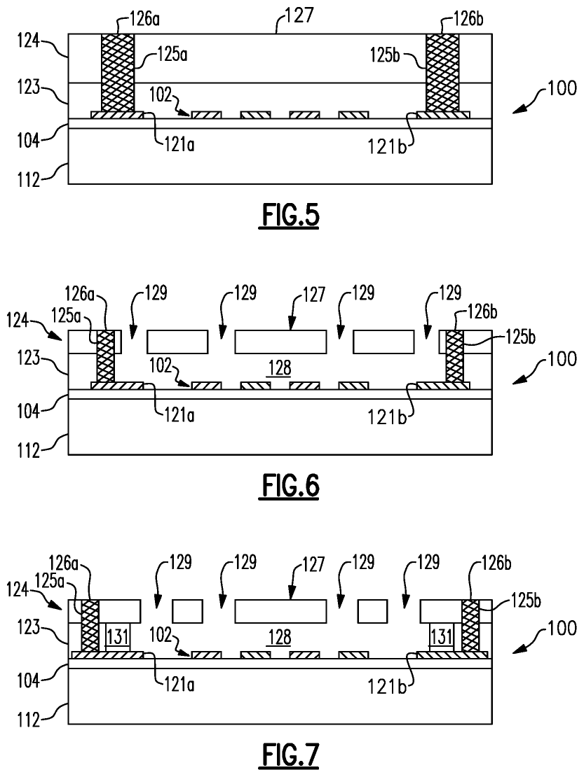

FIG. 7 shows yet another more specific example of the SAW resonator 100 of FIG. 4. In the example of FIG. 7, electrical connections (137a, 137b in FIG. 4) can be implemented as first and second conductive vias 125a, 125b formed through the cap layer 124 and the bonding layer 123. Accordingly, the first via 125a can provide an electrical connection between the first contact pad 121a and an exposed surface 126a (of the first via 125a) at or near the upper surface 127 of the cap layer 124. Similarly, the second via 125b can provide an electrical connection between the second contact pad 121b and an exposed surface 126b (of the second via 125b) at or near the upper surface 127 of the cap layer 124.

In the example of FIG. 7, an internal structure (139 in FIG. 4) can be implemented such that a cavity 128 is provided over the IDT electrode 102. In some embodiments, such a cavity can be defined by an upper surface of the piezoelectric layer 104, an underside surface of the cap layer 124, and a wall structure 131 (e.g., silicon mononitride (SiN)) embedded near a peripheral portion of the bonding layer 123. In such a configuration, the cap layer 124 can include one or more openings 129 extending therethrough and dimensioned to allow formation of the cavity 128.

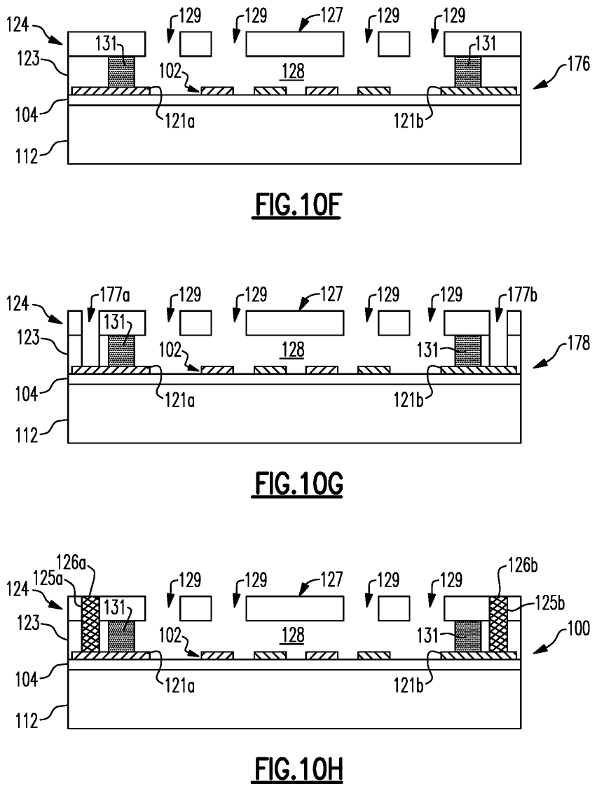

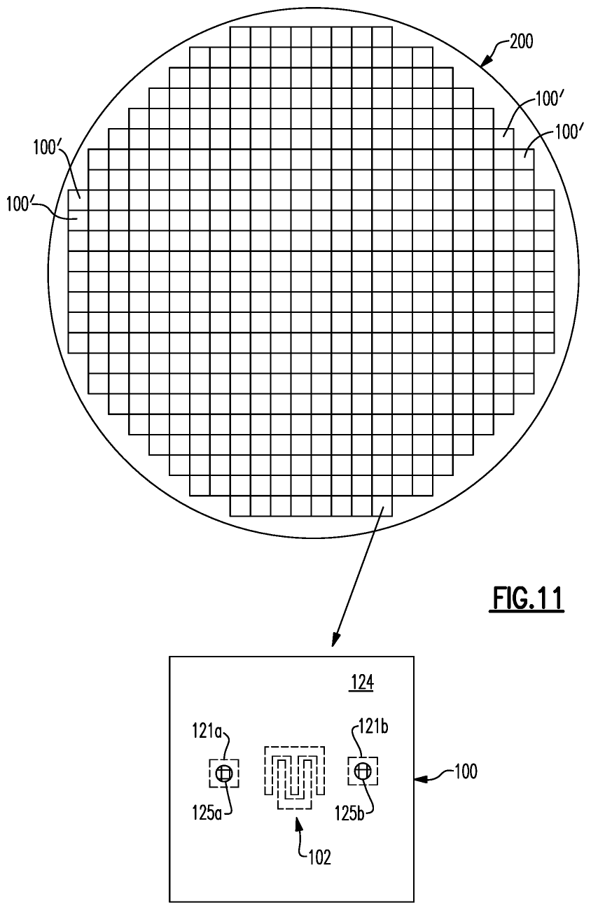

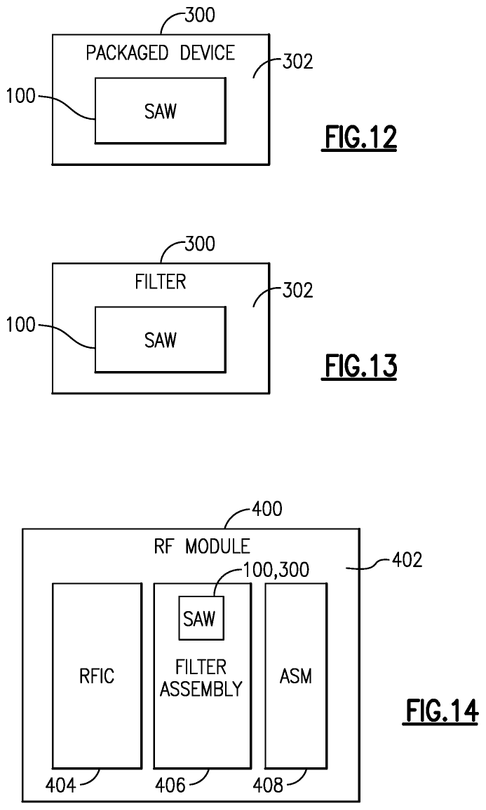

An example of a process that can be utilized to fabricate the SAW resonator 100 of FIG. 7 is described herein in reference to FIGS. 10A-10H.

FIGS. 8A-8H show an example process that can be utilized to manufacture the example SAW resonator 100 of FIG. 5. In such an example process, use of specific materials are described; however, it will be understood that other materials having similar properties can also be utilized.

FIG. 8A shows that in some embodiments, a manufacturing process can include a process step where a relatively thick piezoelectric layer such as a LiTaO₃ (LT) layer 104′ can be formed or provided.

FIG. 8B shows a process step where an interdigital transducer (IDT) electrode 102 and corresponding contact pads 121a, 121b can be formed on a surface of the relatively thick LT layer 104′, so as to result in an assembly 160.

FIG. 8C shows a process step where a bonding layer such as a silicon dioxide (SiO₂) bonding layer 123 can be formed over the relatively thick LT layer 104′, so as to result in an assembly 161. In some embodiments, such a SiO₂ bonding layer can be formed by deposition and polished (e.g., by a chemical mechanical planarization (CMP) process) to result in a flat layer that encapsulates the IDT electrode 102 and the contact pads 121a, 121b.

FIG. 8D shows a process step where a cap layer such as a silicon (Si) cap layer 124 can be bonded to the SiO₂ bonding layer 123, so as to result in an assembly 162.

FIG. 8E shows a process step where the thickness of the relatively thick LT layer 104′ can be reduced to result in an LT layer 104, so as to result in an assembly 163. In some embodiments, such a thinning process step can be achieved by, for example, a polishing process such as a mechanical polishing process, a chemical mechanical process, etc.

FIG. 8F shows a process step where a substrate layer such as a quartz layer 112 can be attached to the LT layer 104, so as to result in an assembly 164. In some embodiments, such an attachment of the quartz layer 112 to the LT layer 104 can be achieved by bonding. In the example of FIG. 8F, the Si cap layer 124 is shown to include a surface 127 (e.g., an upper surface when oriented as shown).

FIG. 8G shows a process step where first and second openings 165a, 165b (e.g., vias) can be formed through the Si cap layer 124 and the SiO₂ bonding layer 123 to expose respective parts of the first and second contact pads 121a, 121b, so as to result in an assembly 166. In some embodiments, such openings can be formed by, for example, patterned etching, etc.

FIG. 8H shows a process step where first and second conductive vias 125a, 125b can be formed by introducing conductive material into the first and second openings 165a, 165b of FIG. 8G, so as to result in a SAW resonator 100 similar to the example of FIG. 5. In some embodiments, such conductive vias can be formed with a conductive material such as a metal. Such conductive material can partially or completely fill the first and second openings to provide respective electrical connections as described herein. In the example of FIG. 8H, the first and second conductive vias 125a, 125b are shown to include respective exposed surfaces 126a, 126b at or near the upper surface 127 of the Si cap layer 124.

FIGS. 9A-9D show an example process that can be utilized to manufacture the example SAW resonator 100 of FIG. 6. In such an example process, use of specific materials are described; however, it will be understood that other materials having similar properties can also be utilized.

FIG. 9A shows that in some embodiments, a manufacturing process can include a process step where an assembly 164 similar to the assembly 164 of FIG. 8F can be formed or provided. Such an assembly can be formed as described herein.

FIG. 9B shows a process step where the Si cap layer 124 can be thinned to expose a surface 127′. One or more openings 129 can be formed through the thinned Si cap layer 124′ to expose respective portions of the SiO₂ bonding layer 123, so as to result in an assembly 168. In some embodiments, such opening(s) can be formed by, for example, patterned etching, etc. In some embodiments, factors such as number, dimension and arrangement of such opening(s) can be selected to allow formation of a cavity as described herein.

FIG. 9C shows a process step where a cavity 128 can be formed over the IDT electrode 102, so as to result in an assembly 169. In some embodiments, such a cavity can be formed by etching (e.g., chemical etching) of a portion of the SiO₂ bonding layer 123 through the opening(s) 129. In the process step of FIG. 9C, the lateral extent of the cavity 128 (where SiO₂ is removed) can be controlled by, for example, the opening(s) 129 and/or duration of the etching process.

FIG. 9D shows a process step where first and second conductive vias 125a, 125b can be formed, so as to result in a SAW resonator 100 similar to the example of FIG. 6. In some embodiments, such conductive vias can be formed by first forming respective openings (e.g., patterned etching of vias) through the Si cap layer 124 and the SiO₂ bonding layer 123 (if present beyond the lateral boundary of the cavity 128) to expose respective parts of the first and second contact pads 121a, 121b, followed by introducing conductive material into the openings. It will be understood that such conductive vias can be formed with conductive material such as a metal, and the conductive material can partially or completely fill the openings to provide respective electrical connections as described herein.

FIGS. 10A-10H show an example process that can be utilized to manufacture the example SAW resonator 100 of FIG. 7. In such an example process, use of specific materials are described; however, it will be understood that other materials having similar properties can also be utilized.

FIG. 10A shows that in some embodiments, a manufacturing process can include a process step where an assembly 170 can be formed or provided. In FIG. 10A, the assembly 170 can include one side of a piezoelectric layer such as a LiTaO₃ (LT) layer 104 attached to a substrate such as a quartz substrate 112, and an interdigital transducer (IDT) electrode 102, corresponding contact pads 121a, 121b, and a bonding layer such as a silicon dioxide (SiO₂) bonding layer 123 implemented on the other side of the LT layer 104. In some embodiments, such an assembly can be formed by, for example, removing a cap layer such as a silicon (Si) cap layer 124 (e.g., by etching) from the assembly 164 described herein in reference to FIG. 8F and FIG. 9A.

FIG. 10B shows a process step where one or more openings 171 can be formed, so as to result in an assembly 172. In some embodiments, such opening(s) can be one or more trenches that partially or fully surrounds the IDT electrode 102 when viewed from the top. For example, one trench can be implemented to surround the IDT electrode 102. In some embodiments, such trench(es) can be formed by, for example, patterned etching, etc.

FIG. 100 shows a process step where the opening(s) 171 of the assembly 172 can be filled with material such as silicon mononitride (SiN) to provide a SiN wall structure 131, so as to result in an assembly 173. In some embodiments, such a SiN wall structure can partially or fully surround the IDT electrode 102 when viewed from the top. For example, if there is one trench 171 surrounding the IDT electrode 102, the resulting SiN wall structure 131 can also surround the IDT electrode 102. In some embodiments, the wall structure 131 can be formed by, for example, deposition of SiN into the trench(es) 171, followed by a polishing process to provide a desired surface including upper portions of the bonding layer 123 and the SiN wall structure 131.

FIG. 10D shows a process step where a cap layer such as a silicon (Si) cap layer 124 can be formed, so as to result in an assembly 174. In some embodiments, a thicker Si layer can be bonded to the SiO₂ bonding layer 123 and be thinned to result in the Si cap layer 124 with an upper surface 127. In such a configuration, the Si cap layer 124 can cover the upper portions of the SiO₂ bonding layer 123 and the SiN wall structure 131.

FIG. 10E shows a process step where one or more openings 129 can be formed through the Si cap layer 124 to expose respective portions of the SiO₂ bonding layer 123, so as to result in an assembly 175. In some embodiments, such opening(s) can be formed by, for example, patterned etching, etc. In some embodiments, factors such as number, dimension and arrangement of such opening(s) can be selected to allow formation of a cavity as described herein.

FIG. 10F shows a process step where a cavity 128 can be formed over the IDT electrode 102, so as to result in an assembly 176. In some embodiments, such a cavity can be formed by etching (e.g., chemical etching) of a portion of the SiO₂ bonding layer 123 through the opening(s) 129. In the process step of FIG. 10F, the SiN wall structure 131 can limit the lateral extent of the cavity 128 even if the etching process would otherwise create a laterally-larger cavity in the absence of a SiN wall structure.

FIG. 10G shows a process step where first and second openings 177a, 177b (e.g., vias) can be formed through the Si cap layer 124 and the SiO₂ bonding layer 123 to expose respective parts of the first and second contact pads 121a, 121b, so as to result in an assembly 178. In some embodiments, such openings can be formed by, for example, patterned etching, etc.

FIG. 10H shows a process step where first and second conductive vias 125a, 125b can be formed by introducing conductive material into the first and second openings 177a, 177b of FIG. 10G, so as to result in a SAW resonator 100 similar to the example of FIG. 7. In some embodiments, such conductive vias can be formed with a conductive material such as a metal. Such conductive material can partially or completely fill the first and second openings to provide respective electrical connections as described herein. In the example of FIG. 10H, the first and second conductive vias 125a, 125b are shown to include respective exposed surfaces 126a, 126b at or near the upper surface 127 of the Si cap layer 124.

FIG. 11 shows that in some embodiments, multiple units of SAW resonators can be fabricated while in an array form. For example, a wafer 200 can include an array of units 100′, and such units can be processed through a number of process steps while joined together. For example, in some embodiments, all of the process steps in each of FIGS. 8A-8H, FIGS. 9A-9D, and FIGS. 10A-10H can be achieved while an array of such units are joined together in a wafer format.

Upon completion of process steps in the foregoing wafer format, the array of units 100′ can be singulated to provide multiple SAW resonators 100. FIG. 11 depicts one of such SAW resonators 100. In the example of FIG. 11, the singulated SAW resonator 100 is representative of the SAW resonator of FIG. 5. It will be understood that the singulated SAW resonator 100 of FIG. 11 can also represent other configurations, including the examples of FIGS. 6 and 7.

FIG. 12 shows that in some embodiments, a SAW resonator 100 having or more features as described herein can be implemented as a part of a packaged device 300. Such a packaged device can include a packaging substrate 302 configured to receive and support one or more components, including the SAW resonator 100. In some embodiments, the packaged device 300 can be configured to provide a radio-frequency (RF) functionality.

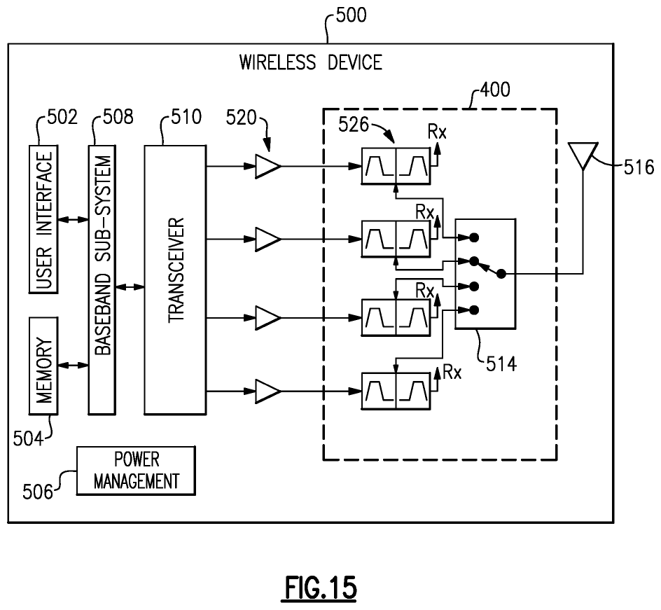

FIG. 13 shows that in some embodiments, the SAW resonator based packaged device 300 of FIG. 12 can be a packaged filter device 300. Such a filter device can include a packaging substrate 302 suitable for receiving and supporting a SAW resonator 100 configured to provide a filtering functionality such as RF filtering functionality.

FIG. 14 shows that in some embodiments, a radio-frequency (RF) module 400 can include an assembly 406 of one or more RF filters. Such filter(s) can be SAW resonator based filter(s) 100, packaged filter(s) 300, or some combination thereof. In some embodiments, the RF module 400 of FIG. 14 can also include, for example, an RF integrated circuit (RFIC) 404, and an antenna switch module (ASM) 408. Such a module can be, for example, a front-end module configured to support wireless operations. In some embodiments, some of all of the foregoing components can be mounted on and supported by a packaging substrate 402.

In some implementations, a device and/or a circuit having one or more features described herein can be included in an RF device such as a wireless device. Such a device and/or a circuit can be implemented directly in the wireless device, in a modular form as described herein, or in some combination thereof. In some embodiments, such a wireless device can include, for example, a cellular phone, a smart-phone, a hand-held wireless device with or without phone functionality, a wireless tablet, etc.

FIG. 15 depicts an example wireless device 500 having one or more advantageous features described herein. In the context of a module having one or more features as described herein, such a module can be generally depicted by a dashed box 400, and can be implemented as, for example, a front-end module (FEM). In such an example, one or more SAW filters as described herein can be included in, for example, an assembly of filters such as duplexers 526.

Referring to FIG. 15, power amplifiers (PAs) 520 can receive their respective RF signals from a transceiver 510 that can be configured and operated in known manners to generate RF signals to be amplified and transmitted, and to process received signals. The transceiver 510 is shown to interact with a baseband sub-system 408 that is configured to provide conversion between data and/or voice signals suitable for a user and RF signals suitable for the transceiver 510. The transceiver 510 can also be in communication with a power management component 506 that is configured to manage power for the operation of the wireless device 500. Such power management can also control operations of the baseband sub-system 508 and the module 400.

The baseband sub-system 508 is shown to be connected to a user interface 502 to facilitate various input and output of voice and/or data provided to and received from the user. The baseband sub-system 508 can also be connected to a memory 504 that is configured to store data and/or instructions to facilitate the operation of the wireless device, and/or to provide storage of information for the user.

In the example wireless device 500, outputs of the PAs 520 are shown to be routed to their respective duplexers 526. Such amplified and filtered signals can be routed to an antenna 516 through an antenna switch 514 for transmission. In some embodiments, the duplexers 526 can allow transmit and receive operations to be performed simultaneously using a common antenna (e.g., 516). In FIG. 15, received signals are shown to be routed to “Rx” paths (not shown) that can include, for example, a low-noise amplifier (LNA).

Unless the context clearly requires otherwise, throughout the description and the claims, the words “comprise,” “comprising,” and the like are to be construed in an inclusive sense, as opposed to an exclusive or exhaustive sense; that is to say, in the sense of “including, but not limited to.” The word “coupled”, as generally used herein, refers to two or more elements that may be either directly connected, or connected by way of one or more intermediate elements. Additionally, the words “herein,” “above,” “below,” and words of similar import, when used in this application, shall refer to this application as a whole and not to any particular portions of this application. Where the context permits, words in the above Detailed Description using the singular or plural number may also include the plural or singular number respectively. The word “or” in reference to a list of two or more items, that word covers all of the following interpretations of the word: any of the items in the list, all of the items in the list, and any combination of the items in the list.

The above detailed description of embodiments of the invention is not intended to be exhaustive or to limit the invention to the precise form disclosed above. While specific embodiments of, and examples for, the invention are described above for illustrative purposes, various equivalent modifications are possible within the scope of the invention, as those skilled in the relevant art will recognize. For example, while processes or blocks are presented in a given order, alternative embodiments may perform routines having steps, or employ systems having blocks, in a different order, and some processes or blocks may be deleted, moved, added, subdivided, combined, and/or modified. Each of these processes or blocks may be implemented in a variety of different ways. Also, while processes or blocks are at times shown as being performed in series, these processes or blocks may instead be performed in parallel, or may be performed at different times.

The teachings of the invention provided herein can be applied to other systems, not necessarily the system described above. The elements and acts of the various embodiments described above can be combined to provide further embodiments.

While some embodiments of the inventions have been described, these embodiments have been presented by way of example only, and are not intended to limit the scope of the disclosure. Indeed, the novel methods and systems described herein may be embodied in a variety of other forms; furthermore, various omissions, substitutions and changes in the form of the methods and systems described herein may be made without departing from the spirit of the disclosure. The accompanying claims and their equivalents are intended to cover such forms or modifications as would fall within the scope and spirit of the disclosure.

1. A surface acoustic wave device comprising:
a quartz substrate;
a piezoelectric film formed from LiTaO₃ or LiNbO₃ and disposed over the quartz substrate;
an interdigital transducer electrode formed over the piezoelectric film;
a bonding layer implemented over the piezoelectric film; and
a cap layer formed over the bonding layer to thereby substantially confine energy of a propagating wave below the cap layer.

2. The acoustic wave device of claim 1 wherein the bonding layer is formed from SiO₂.

3. The acoustic wave device of claim 1 wherein the cap layer is formed from Si.

4. The acoustic wave device of claim 1 wherein the interdigital transducer electrode is formed directly on an upper surface of the piezoelectric film, and a lower surface of the cap layer is in direct contact with an upper surface of the bonding layer.

5. The acoustic wave device of claim 4 wherein the bonding layer encapsulates the interdigital transducer electrode.

6. The acoustic wave device of claim 4 wherein a volume above the interdigital transducer electrode includes a cavity defined by the upper surface of the piezoelectric film and the lower surface of the cap layer, such that the interdigital transducer electrode is exposed to the cavity.

7. The acoustic wave device of claim 6 wherein the cavity is further defined laterally by a side wall.

8. The acoustic wave device of claim 7 wherein the side wall is formed by a peripheral portion of the bonding layer.

9. The acoustic wave device of claim 7 wherein the side wall is formed by a wall structure at least partially embedded within the bonding layer.

10. The acoustic wave device of claim 9 wherein the wall structure includes one or more trenches filled with SiN, the one or more trenches partially or fully surrounding the cavity.

11. (canceled)

12. (canceled)

13. The acoustic wave device of claim 1 further comprising first and second contact pads formed over the piezoelectric film and electrically connected to the interdigital transducer electrode.

14. The acoustic wave device of claim 13 further comprising a conductive via that extends from each of the first and second contact pads to an upper surface of the cap layer.

15. The acoustic wave device of claim 1 further comprising first and second reflectors implemented on the piezoelectric film and positioned on first and second sides of the interdigital transducer electrode.

16. A method for fabricating an acoustic wave device, the method comprising:
forming or providing a piezoelectric layer formed from LiTaO₃ or LiNbO₃;
forming an interdigital transducer electrode over the piezoelectric layer;
implementing a bonding layer over the piezoelectric layer;
bonding a cap layer onto the bonding layer such that the bonding layer is between the cap layer and the piezoelectric layer, the cap layer configured to allow confinement of energy of a propagating wave to a volume below the cap layer; and
thinning the piezoelectric layer to provide a piezoelectric film.

17. The method of claim 16 further comprising attaching a quartz substrate onto the piezoelectric film.

18. (canceled)

19. (canceled)

20. (canceled)

21. The method of claim 16 wherein the implementing of the bonding layer results in the bonding layer encapsulating the interdigital transducer electrode.

22. The method of claim 16 wherein the implementing the bonding layer results in a cavity above the interdigital transducer electrode and defined by the first surface of the piezoelectric film and a lower surface of the cap layer, such that the interdigital transducer electrode is exposed to the cavity.

23. (canceled)

24. (canceled)

25. The method of claim 22 further comprising embedding a wall structure at least partially within the bonding layer, such that the wall structure forms a side wall of the cavity.

26. The method of claim 16 further comprising forming first and second conductive vias through the cap layer and the bonding layer to provide an electrical connection for each of first and second contact pads associated with the interdigital transducer electrode to a location at or near an upper surface of the cap layer.

27. A radio-frequency filter comprising:
an input node for receiving a signal;
an output node for providing a filtered signal; and
an acoustic wave device implemented to be electrically between the input node and the output node to generate the filtered signal, the acoustic wave device including a quartz substrate, a piezoelectric film formed from LiTaO₃ or LiNbO₃ and disposed over the quartz substrate, and an interdigital transducer electrode formed over the piezoelectric film, the surface acoustic wave device further including a bonding layer implemented over the piezoelectric film, and a cap layer formed over the bonding layer to thereby substantially confine energy of a propagating wave below the cap layer.

28. (canceled)

29. (canceled)
